(19) United States
(12) Patent Application Publication
(10) Pub. No.: US 2026/0171345 A1
(43) Pub. Date: Jun. 18, 2026

(54) BATTERY STATE CONTROL DURING CROSS-SECTION BEAM MILLING

(71) Applicant: FEI Company, Hillsboro, OR (US)

(72) Inventors: Ondrej Klvac, Brno (CZ); David Trochta, Znojmo (CZ); Jan Lásko, Brno (CZ); Libor Novák, Brno (CZ); Peter Priecel, Vnorovy (CZ)

(73) Assignee: FEI Company, Hillsboro, OR (US)

(21) Appl. No.: 18/986,286

(22) Filed: Dec. 18, 2024

(51) Int. Cl. H01J 37/20; H01J 37/304; H01J 37/31

(52) U.S. Cl. CPC H01J 37/20; H01J 37/304; H01J 37/31; H01J 2237/026; H01J 2237/2007; H01J 2237/24585; H01J 2237/30472; H01J 2237/3109

(57) ABSTRACT

Sample shuttles are operable to electrically contact and secure samples during and after ion beam milling. During sample processing with an ion beam incident to a first sample surface along a first direction, sample electrical characteristics such as voltage or impedance are measured. Based on the measurements, sample electrical characteristics are adjusted by applying a voltage or a current, the sample shuttle is rotated to permit sample milling from a second direction. A non-conductive mask can be situated to reduce redeposition of material from shuttle surfaces on samples.

### FIELD

The disclosure pertains to electrical control and assessment of samples during ion beam milling.

### BACKGROUND

Broad ion beam (BIB) milling systems have been developed for use in preparing samples for investigation using electron microscopy. BIB milling can replace conventional cutting, grinding, and polishing operations which are either impractical or difficult for some kinds of samples. The conventional approaches can result in surfaces that exhibit sample preparation induced defects so that determination of actual sample condition is challenging. In addition, BIB milling has been implemented with systems that retain samples in a controlled environment to avoid exposure of BIB milling surfaces to air or other environments that damage or otherwise alter sample surfaces. Combining a controlled environment with BIB milling enables preparation and inspection of high-quality surfaces of difficult samples such as soft or reactive materials.

Unfortunately, for some samples of interest, redeposition of material removed by BIB can produce sample damage. In addition, it can be difficult both to monitor the condition of a sample and to secure the sample properly during BIB milling. For some samples such as some types of batteries, inattention to battery charge state can result in battery damage, rendering further processing and assessment of little value. For these reasons, improved BIB milling approaches are needed.

### SUMMARY

Disclosed herein are shuttles for holding a battery or other sample during cross-section preparation in broad ion beam (BIB) polishing system. The disclosed shuttles provide electrical connections to samples mounted in the shuttle so that currents, voltages, and impedance can be measured or voltages or currents applied to the sample using, for example, a galvantostat, potentiostat, or other electronics during milling or other processing with an ion beam such as a broad ion beam (BIB). Not only can the disclosed shuttles provide electrical connections, but samples retained in shuttles can be compressed using shuttle jaws and samples retained in shuttles transported for other evaluation and processing procedures such as imaging in an electron microscope or optical microscope. In addition, processing systems are provided in which a shuttle and a sample retained in the shuttle are maintained in a controlled environment such as an argon gas environment. In BIB or other operations applied to a sample battery, battery voltage can be maintained during milling and established or re-stablished with the shuttle before transfer away from the BIB system. Battery discharge times can be measured with a battery situated in a shuttle, and the battery recharged as needed before or after transfer based on measured discharge time. A shuttle retaining a battery can be rotated or otherwise repositioned so that the battery can be subject to cross-sectional milling and/or flat milling so that debris produced by cross-sectional milling can be removed by flat milling or vice versa. In some examples, insulative shields are provided so that milling beams do not produce conductive debris from shuttle components that is deposited on a sample or other workpiece.

The foregoing and other features, and advantages of the disclosure will become more apparent from the following detailed description, which proceeds with reference to the accompanying figures.

### BRIEF DESCRIPTION OF THE DRAWINGS

FIG. 1A illustrates a representative shuttle that permits electrical connections to a battery retained in a sample volume.

FIG. 1B illustrates a portion of the shuttle of FIG. 1A.

FIG. 1C is a perspective view of the battery of FIG. 1A.

FIG. 1D illustrates the shuttle of FIGS. 1A-1B as secured to a base.

FIG. 2 illustrates another representative shuttle.

FIG. 3A illustrates a processing system in which a sample is secured to a shuttle for transport between a BIB milling system and an SEM in a controlled environment, with the sample positioned for cross-sectional milling.

FIG. 3B illustrates the BIB milling system of FIG. 3A with the sample positioned for top surface milling.

FIG. 4 illustrates a shuttle secured to a translatable base.

FIG. 4A illustrates the translational base of FIG. 4.

FIG. 4AA is a sectional view of the translational base of FIG. 4A.

FIG. 5 illustrates a shuttle secured to a translatable base.

FIG. 5A is a sectional view of the translational base of FIG. 5.

FIG. 6A is an elevational view of a shuttle secured to a translatable base that is situated in a guide.

FIG. 6B illustrates the translatable base and guide of FIG. 6A.

FIG. 6C-6D illustrate a positioning member for use in moving the shuttle of FIG. 6A along the guide.

FIG. 7 illustrates an additional representative shuttle.

FIG. 8 illustrates a representative method of ion beam milling a battery retained in a shuttle.

FIG. 9A is a sectional view of a shuttle that includes a non-conductive mask.

FIGS. 9B-9C illustrate additional representative examples of shuttles that include non-conductive masks.

### DETAILED DESCRIPTION

The disclosed approaches provide methods, systems, and apparatus that permit ion beam milling such as broad ion beam (BIB) milling of samples such as batteries or other devices while monitoring, correcting, and adjusting electrical characteristics of the sample. In a particular example, batteries are secured for BIB milling while measuring anode-cathode impedance or anode-cathode voltage and adjusting battery voltage. For convenience, sample mounting apparatus are referred to herein as “shuttles.” In many cases it is advantageous or necessary to move or “shuttle” a sample between an ion beam milling apparatus such as a BIB apparatus and a charged-particle imaging apparatus such as a scanning electron microscope. In some examples in which samples are moved or shuttled, the sample is kept in a controlled environment such as a noble gas environment during shuttling. However, unless otherwise indicated, a shuttle need not provide any particular movement capability or shuttling but need only serve to secure or retain a sample. Examples of systems suitable for sample shuttling within or between processing systems such as BIB systems and evaluation systems such as SEMs are described in U.S. Pat. App. Publ. 2023/0132874 and U.S. Pat. App. Publ. 2023/0420216, both of which are incorporated herein by reference.

### General Terminology

As used herein, guide portions or channels or protrusions are defined so that a channel defined on a first part is engageable with a protrusion defined on a second part, wherein the channel and protrusion define a translation axis and constrain movement to be along the translation axis. Examples include a rectangle slots and corresponding rectangular protrusions, channels having dovetail shapes and corresponding protrusions, or other combinations of shapes defined by curves or straight lines. Such engageable parts are referred to herein as “complementary.”

“Controlled environment” refers to an environment based on an inert gas, mixtures of inert gases or other gases or other mixtures that tend to leave sample properties unaltered after exposure as well as vacuum in which samples are substantially unexposed.

“Orthogonal” refers to angles that are within a range of 90 degrees ±2 degrees, ±5 degrees, ±10 degrees, or ±15 degrees from perpendicular.

Examples of the disclosure pertain to ion beam milling of batteries. As used herein a battery includes an anode and a cathode with an electrolyte situated between the anode and the cathode. Anodes and cathodes are generally formed of conductive material that are substantially smaller in a thickness dimension than in other directions. As used herein, “edge” refers to a surface terminated along an anode or cathode thickness, i.e., an exposed thinnest surface. “Electrode” refers to either an anode or a cathode.

While electrical resistance (in Ohms) is a convenient measure of electrical connection between an anode and a cathode of a battery, other measures such as conductivity, conductance or impedance can also be obtained.

### Example 1

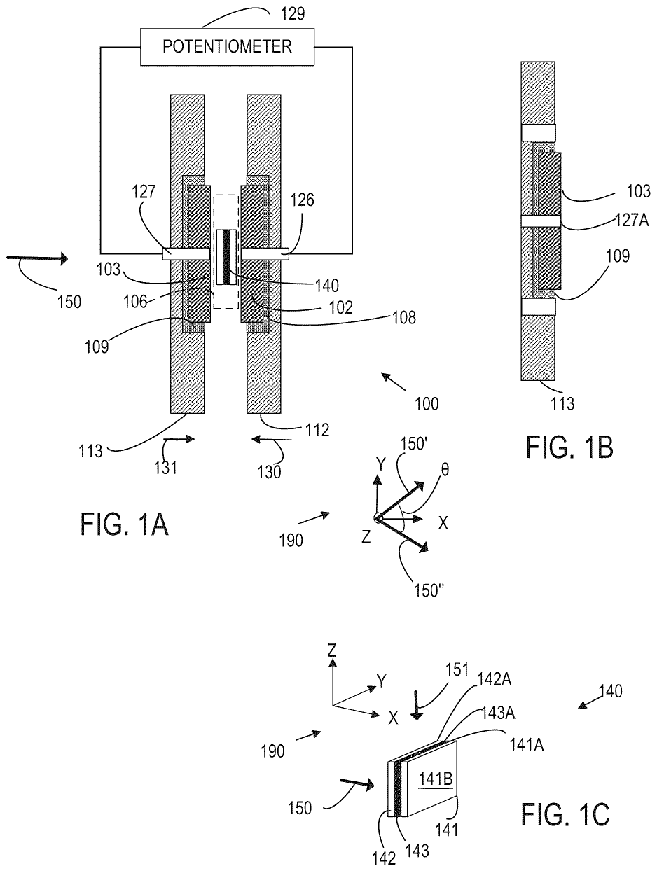

Referring to FIG. 1A, a representative sectional view of a battery shuttle 100 includes conductive inserts 102, 103 situated to be urged toward a volume 106 along directions 130, 131 toward and away from a volume 106 adapted to receive a battery 140 or other sample. The conductive inserts 102, 103 are in contact with insulative spacers 108, 109 that contact jaws 112, 113 that can be moved towards and away from each other. Electrical connections to a battery disposed in the volume 106 can be made with feedthroughs 126, 127 that typically include a central conductor embedded in an insulative sleeve. As shown in FIG. 1A, the feedthroughs 126, 127 are coupled to a galvanostat/potentiostat 129 or other suitable electrical circuitry for measurement and/or control of one or more of voltage, current, and impedance associated with a battery in the volume 106 and/or application of a current or voltage to the battery.

FIG. 1B illustrates the arrangement of the conductive insert 103, the insulative spacer 109, and the jaw 113 without the electrical feedthrough 127 which in use, is inserted into or passes through a bore 127A. In FIGS. 1A-1B these bores and the associated screws, alignment pins, and electrical feedthroughs are shown in a common cross-section in an XY-plane of a coordinate system 190; in typical implementations, some or all of these are in different XY-planes and the arrangement of FIGS. 1A-1B is used for convenient illustration.

As shown in FIG. 1C, the battery 140 includes first and second electrodes 141, 142 with an electrolyte 143 situated between. The electrodes can be referred to as plates or plate-like as they typically have dimensions in Y-and Z-directions of the coordinate system 190 that are at least 5, 10, 20, 50, or 100 times greater that a dimension in an X-direction. For convenience, electrode dimensions along the X-axis are referred to at thicknesses herein. Electrode surfaces such as surface 141B are referred to herein as major surfaces to contrast with electrode thickness. As shown also in FIG. 1C (and partially in FIG. 1A), the shuttle 100 can be arranged so that an ion beam is incident along an axis 150 to surfaces for cross-sectional milling or along an axis 151 so that the ion beam is directed to surfaces 141A, 142A, 143A of the electrodes 141, 142 and electrolyte 143 for top surface milling. Cross-sectional milling or top surface milling is generally selected by rotation of the shuttle with respect to an ion beam source, or by positioning of the ion source with respect to the sample. The axes 150, 151 are illustrate at particular angles for convenient explanation, but a variety of angles can be selected, typically different axes for cross-sectional milling and to surface milling. For example, axes 150′, 150′″ can be used for cross-sectional milling, or any axis within a cone defined by a cone angle θ, wherein θ ≤5, 10, 20, 30, or 45 degrees. Similarly, axes within a cone angle φ with respect to an-Z-axis as shown in FIG. 1C can be used for top surface milling, wherein φ≤5, 10, 20, 30, or 45 degrees. However, still other axes can be used as may be convenient for one or both of cross-sectional milling and top surface milling.

FIG. 1D illustrates the battery shuttle 100 in which one of the jaws 112, 113 is secured to a base plate 160 and the other is movable to secure and contact a battery disposed in the volume 106. Electrical connections to the conductive inserts 102, 103 are made via conductive pins or terminals 164, 165 secured to the base plate 160.

### Example 2

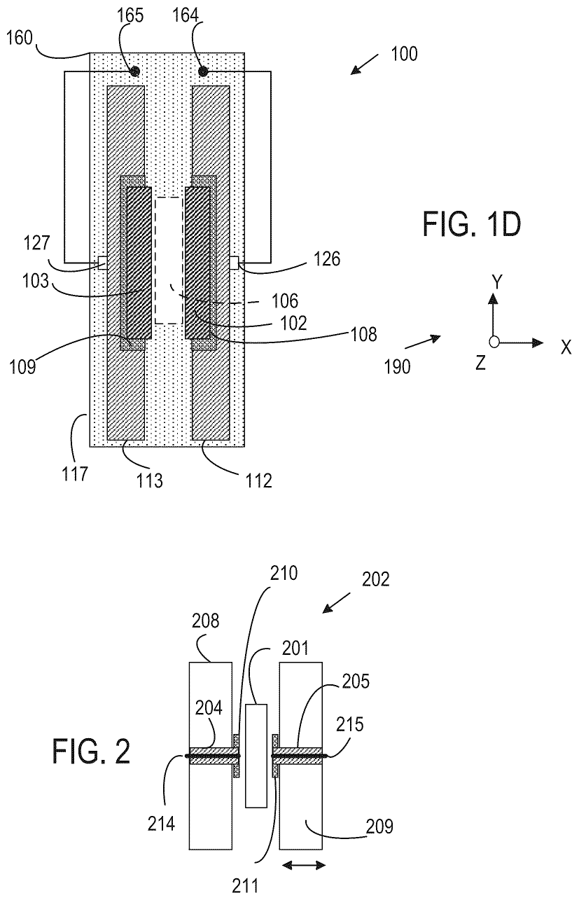

In another example illustrated in FIG. 2, a shuttle 202 incudes insulating feedthroughs 204, 205 that extend through shuttle jaws 208, 209 to respective insulating pressure plates 210, 211 to contact a sample 201 via central conductors 214, 215.

### Example 3

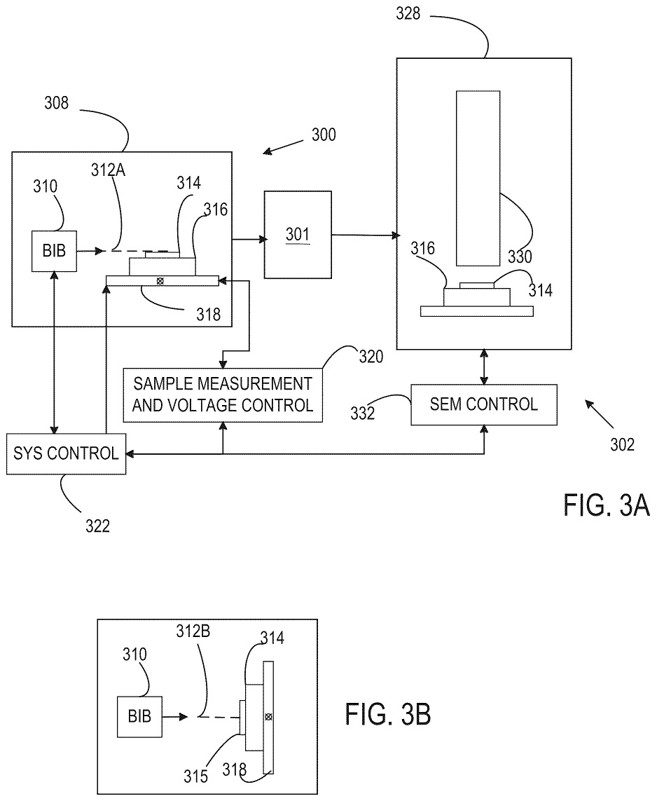

Referring to FIGS. 3A-3B, a representative system includes a BIB processing system 300, a transport system 301 that is operable to maintain a sample in a controlled environment transiting between the BIB processing system 300 and a SEM or other imaging system 302 that permits sample viewing and assessment. The BIB system 300 includes a BIB source 310 or other ion beam source that is operable to direct a BIB along a sample axis 312A to a sample 314 situated in an enclosure 308 that establishes a controlled atmosphere. The sample 314 is retained by a shuttle 316 such as described herein. The shuttle 316 is mounted to a stage 318 that can provide arbitrary translations and rotations as needed so that the BIB is incident to the sample at suitable locations and angles. The sample 314 is electrically connected to an electrical measurement and control system 320 that is operable to measure sample voltage, current, and impedance and apply voltages or currents prior to, during, and after BIB milling.

In BIB milling of batteries, the electrical system 320 can be operated to measure battery impedance and voltage during BIB milling. When battery voltage drops below a predetermined limit, the electrical system 320 can charge the battery as is required to avoid battery damage for some types of batteries. The electrical system 320 can also measure battery impedance. In some cases, debris produced during BIB milling reduces electrical resistance between battery electrodes and determination of a low or falling impedance and/or voltage can be used to indicate milling is required to remove this debris. In this case, the sample stage 318 is operated to rotate the shuttle 316 so that the BIB is incident to the sample 314 along a sample axis 312B, different from the sample axis 312A, to remove debris as illustrated in FIG. 3B.

Electrical characteristics of the sample 314 are detected and voltages or currents applied with sample electronics 320 that can include voltage, current, and impedance measurement electronic and current and voltage sources. A system controller 322 is coupled to the BIB source 310l, the stage 318, and the sample electronics 320 for operation of each as needed.

The transport system 301 can be arranged so that the sample 314 and the sample shuttled can be transferred to a chamber 328 of the imaging system 302 in a controlled environment. The imaging system 302 includes a charged-particle optical column 330 (charged-particle source, lens, deflectors, detectors, etc.) situated to image the sample 314 operable in response to the system controller 322.

### Example 4

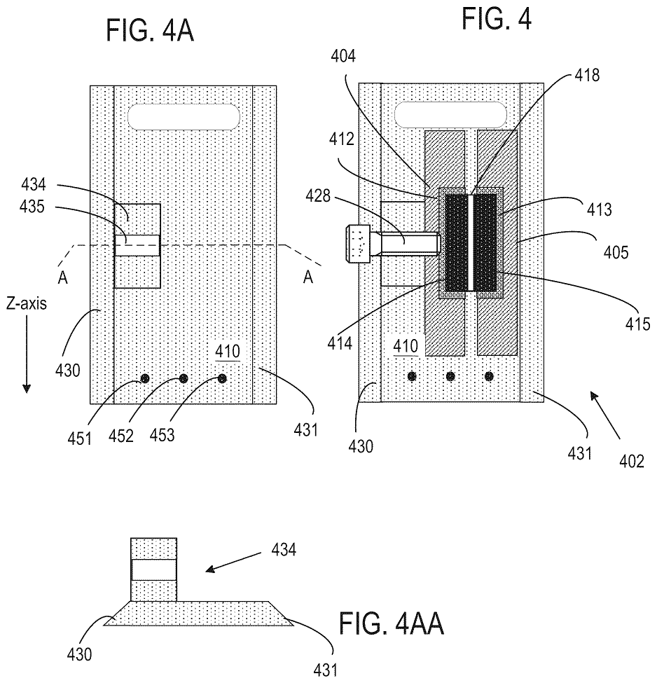

Referring to FIG. 4, a sample shuttle 402 includes a first jaw 404 and a second jaw 405, wherein the second jaw 405 is secured to a translatable base 410 with one or more screws or other fasteners. Respective first and second insulators 412, 413 are shown pressed against respective conductive plates 414, 415 that define a sample volume 418. A sample situated in the sample volume 418 can be electrically coupled to electronic measurement systems or to current and voltage sources without electrical contact to the translatable base 410 or the first and second jaws 404, 405. In operation, the jaw faces remain substantially parallel as a screw 428 or other mechanism is engaged to urge the first jaw 404 towards the second jaw 405.

The translatable base 410 includes first and second tapered edges 430, 431 selected to fit into a corresponding groove for stable translation of the shuttle 402 in a guide track (not shown) in the direction of a Z-axis. FIG. 4A illustrates the translatable base 410 to which contact pins 451-453 are secured. A member 434 is secured to the translatable base 410 and defines a threaded hole 435 adapted to the screw 428. FIG. 4AA is a sectional view of the translatable base illustrating the tapered edges 430, 431.

### Example 5

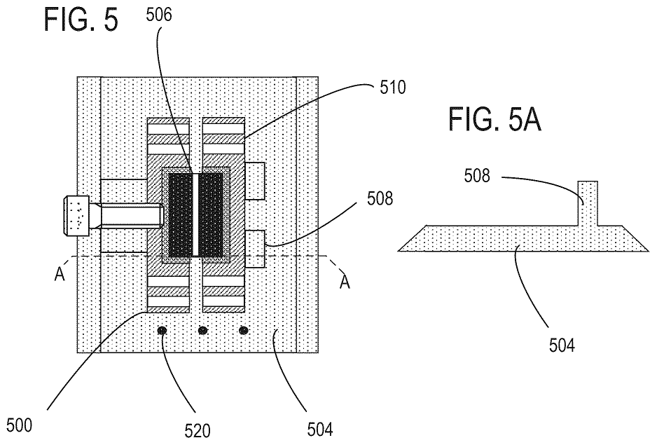

FIGS. 5-5A illustrate a sample shuttle 500 situated on a translatable base 504 and defining a sample cavity 506. In this example, as shown in the sectional view of FIG. 5A, the translatable base 504 includes a projection 508 that is situated to restrain a jaw 510 of the sample shuttle 500. One or more electrical contacts such as representative contact 520 are secured to the translatable base 504 and are electrically coupled to the sample cavity 506.

### Example 6

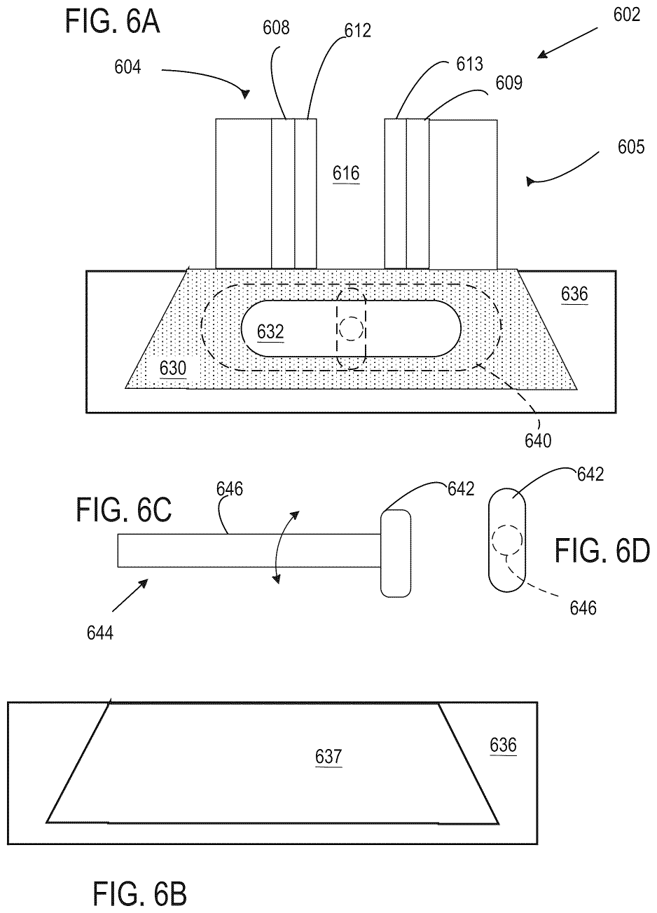

FIGS. 6A-6B illustrate a shuttle 602 that includes a first jaw 604 and a second jaw 605 that are provided with respective insulators 608, 609 and conductive pressure plates 612, 613 that are operable to electrically contact and secure a sample such as a battery situated in a sample volume 616. The first jaw 608 can be urged toward the second jaw 609 to secure and contact a sample.

The shuttle 602 is secured to a base 630 that is retained in a channel 637 defined in a guide 636 to permit translation along an axis of the guide 636. An aperture 632 is defined in the guide 636 to permit access to a cavity 640. Referring to FIGS. 6C-6D, and end portion 642 of a positioning member 644 is insertable into the cavity 640 through the aperture 632 and rotatable so that the positioning member 644 can translate the base 630 along the axis of the base 630. In typical examples, the positioning member 640 include a rod 646 that is coupled to the end portion 642.

### Example 7

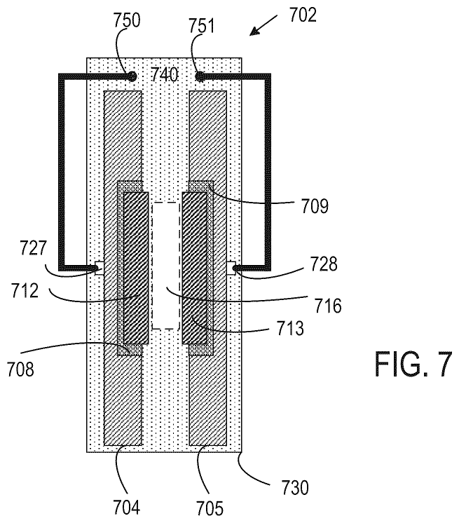

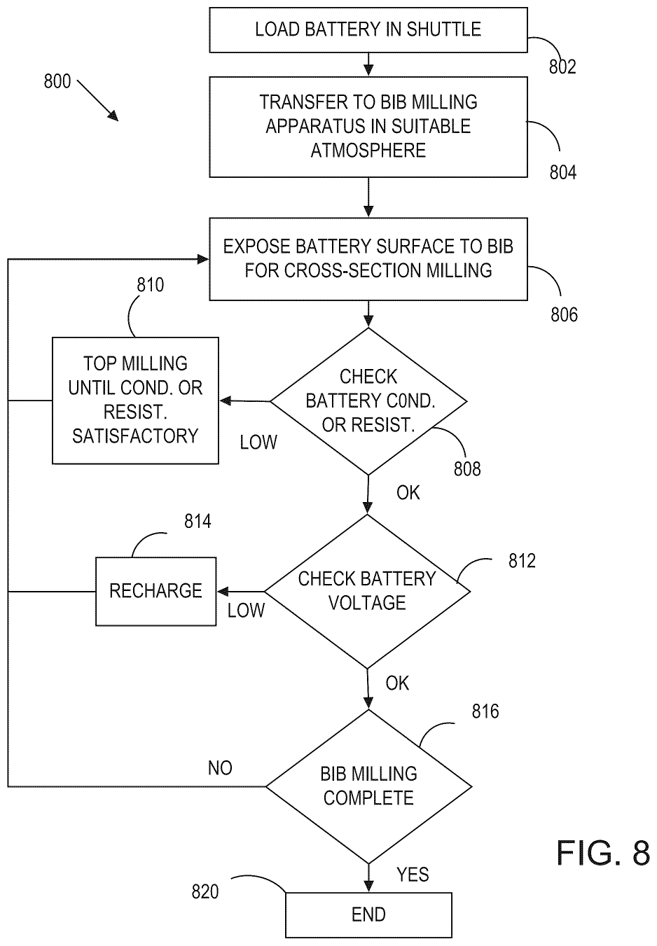

FIG. 7 illustrates a shuttle 702 that includes a first jaw 704 and a second jaw 705 that are provided with respective insulators 708, 709 and conductive pressure plates 712, 713 that are operable to electrically contact and secure a sample such as a battery situated in a sample volume 716. Screws or other mechanisms can be situated to urge the first jaw 704 and the second jaw 705 toward each other to secure and contact a sample. The shuttle 702 is secured to a base 730 that can be retained in a channel permit translation along an axis of a guide.

In the example of FIG. 7, electrical connections to the sample volume 716 are provided by electrical feedthroughs 727, 728 that extend through the insulators 708, 709 and the conductive plates 712, 713. These are electrically connected via wires or conductive strips to connection terminals 750, 751.

### Example 8

A representative method 800 of ion beam milling such as BIB milling a battery includes loading a battery in a shuttle at 802 and transferring the shuttle to a BIB apparatus at 804, preferably in a controlled atmosphere. At 806, an exposed battery surface is milled along a battery edge. At 808, a battery impedance, conductance, conductivity or other parameter associated with an electrical impedance of the battery is measured. For measurements that indicate a relatively lower than preferred impedance, the milling ion beam is directed for top milling at 810, wherein the axis of the ion beam is parallel to a major surface of the anode or cathode. After top milling at 810, the ion beam is again directed for cross-sectional milling at a battery edge at 806. In most practical applications an axis of the milling ion beam remains substantially the same and the shuttle is rotated to change an ion beam milling direction.

For same types of batteries, maintenance of a selected battery voltage is required to avoid battery failure or other changes rendering further processing of little interest. For this reason, at 812, battery voltage is checked, and in some cases such as for battery voltage that has become too low, the battery is recharged at 814 to be at an appropriate voltage. If battery voltage and battery anode-cathode impedance are acceptable, at 816, a determination is made to continue milling and return to 806 or to discontinue milling at 816. In performing the method 800, the battery is maintained in a controlled environment and can be shuttled to an SEM or other charged-particle imaging systems in the same or a different controlled environment. Battery impedance and voltage are typically continuously or periodically monitored during milling so that a milling direction can be changed at 810 or the battery recharged at 814.

### Example 9

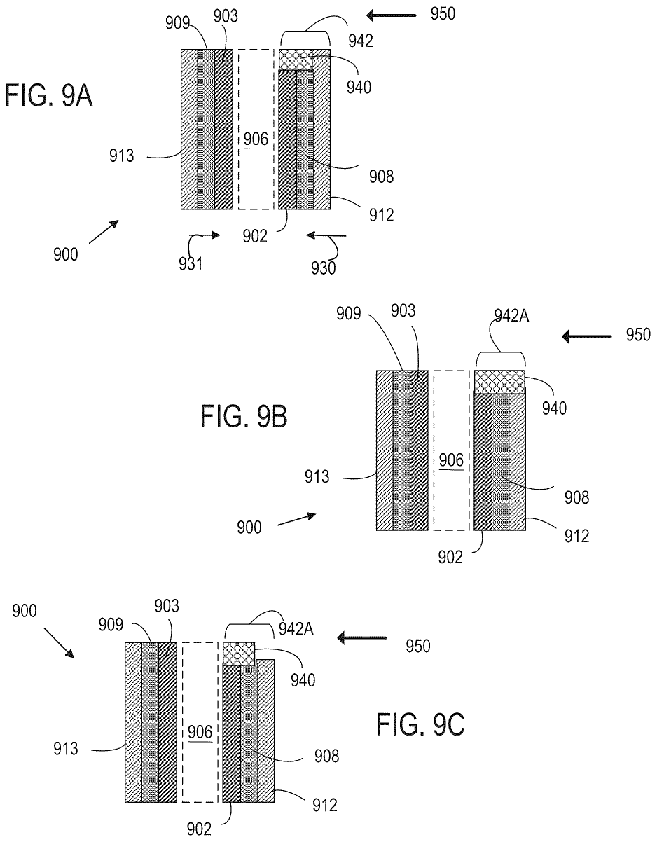

In some cases, BIB milling can result in portions of conductive inserts, jaws, or other portions of shuttles being milled and redeposited on surfaces of workpieces. This is especially problematic with BIB milling of batteries in which deposition of conductive materials on battery surfaces can result is electrical short circuits. By providing a suitable mask, preferably a non-conductive mask, problems associated with redeposition can be reduced or avoided. Referring to FIG. 9A, a representative sectional view of a battery shuttle 900 includes conductive inserts 902, 903 situated to be urged along directions 930, 931 toward and away from a volume 906 adapted to receive a battery or other sample or workpiece. The conductive inserts 902, 903 are in contact with insulative spacers 908, 909 that contact jaws 912, 913 that can be moved towards and away from each other. Electrical connections to a battery disposed in the volume 906 can be made with feedthroughs or otherwise as discussed above.

As shown in FIG. 9, a BIB 950 is directed toward the shuttle 900 across upper surfaces of the conductive inserts 902, 903, insulative spacers 908, 909, and jaws 912, 913 but an insulative mask 940 is situated to cover at least an upper portion of the conductive insert 902. In this arrangement, the conductive insert 902 is unmilled by the BIB 950 and BIB milling does not result in redeposition of material from the conductive insert 902 onto a sample in the volume 906. In the example of FIG. 9, the mask 940 also covers an upper portion of the insulative spacer 908. In other examples, the mask 940 is situated to cover surfaces of the conductive insert 902, the insulative spacer 908, and the jaw 912. It is generally more important to cover surfaces situated upstream of a sample with respect to the BIB 950 across which the BIB is directed to reduce redeposition (i.e., upstream surfaces as indicated at 942) but a mask can be provided for downstream surfaces as well. The mask 940 is preferably non-conductive such as glass, aluminum oxide, polyether ether ketone (PEEK), polytetrafluoroethylene (PTFE), or poly(methyl methacrylate) (PMMA) so that any redeposited material does not produce undesired alteration in a sample. For example, redeposition of glass or other non-conductive material does not produce electrical short circuits in batteries subjected to BIB milling.

FIGS. 9B-9C illustrate other example shuttles having insulative masks. In the example of FIG. 9B, an insulative mask 942A covers top surfaces of the jaw 912 and the insulative spacer 908. In the example of FIG. 9C, an insulative mask 942B covers a top surface of the conductive insert 902 and the jaw 912 is recessed at the top surface. In these examples, shuttles are arranged so that a milling beam is not directed toward conductive portions of the shuttles. Milling direction can also be selected to reduce or avoid milling beam interaction with conductive portions of shuttles to reduce or eliminate redeposition.

### Disclosure Clauses

Clause 1 is a shuttle for securing a sample, including a first jaw and a second jaw, the first jaw operable to be urged toward the second jaw, the first jaw and the second jaw defining a sample volume situated between an inner surface of the first jaw and an inner surface of the second jaw; and a shuttle base that includes a first electrical contact and a second electrical contact electrically coupled to the sample volume proximate the first jaw and the second jaw, respectively.

Clause 2 includes the subject matter of Clause 1, and further includes: a first conductive pressure plate having a first surface that defines a least a first portion of perimeter surface of the sample volume and a second surface, opposite the first surface, facing the first jaw; and a second conductive pressure plate having a first surface that defines a least a second portion of perimeter surface of the sample volume opposite the first portion and a second surface, opposite the first surface, facing the second jaw, wherein the first conductive pressure plate and the second conductive pressure plate are operable to electrical connect to a sample situated in the sample volume in response to response to the first jaw being urged toward the second jaw.

Clause 3 includes the subject matter of any of Clauses 1-2, and further includes: a first insulator situated at an inner surface of the first jaw to electrically insulate the first jaw from the first conductive pressure plate and a second insulator situated at an inner surface of the second jaw to electrically insulate the second jaw from the second conductive pressure plate.

Clause 4 includes the subject matter of any of Clauses 1-3, and further specifies that the second jaw is fixed to the shuttle base.

Clause 5 includes the subject matter of any of Clauses 1-4, and further includes: a first insulator situated at an inner surface of the first jaw to electrically insulate the first jaw from the sample volume; and a second insulator situated at an inner surface of the second jaw to electrically insulate the second jaw from the sample volume.

Clause 6 includes the subject matter of any of Clauses 1-5, and further specifies that the second jaw is fixed to the shuttle base.

Clause 7 includes the subject matter of any of Clauses 1-6, and further includes a screw mechanism secured to the shuttle base and operable to urge the first conductive pressure plate toward the second conductive pressure plate.

Clause 8 includes the subject matter of any of Clauses 1-7, and further specifies that the shuttle base defines a shuttle axis of translation.

Clause 9 includes the subject matter of any of Clauses 1-8, and further specifies that the shuttle base has a dovetailed cross-section in a plane perpendicular to a shuttle axis of translation.

Clause 10 includes the subject matter of any of Clauses 1-9, and further specifies that the shuttle base defines an aperture operable to releasably retain a positioning member.

Clause 11 is a shuttle system, including: the shuttle of any of examples 1-10; and a shuttle guide engageable with the shuttle base so that the shuttle is translatable along the shuttle axis of translation as engaged with the shuttle guide.

Clause 12 includes the subject matter of Clause 11, and further specifies that the shuttle base and the shuttle guide have complementary engageable dovetail cross-sections that are perpendicular to the shuttle axis of translation.

Clause 13 is a shuttle system, including: the shuttle of any of examples 1-9; and an electronic interface electrically coupled to the first electrical contact and the second electrical contact of the shuttle base and operable to establish a voltage of a sample situated in the shuttle or determine a impedance or a voltage associated with the sample situated in the shuttle.

Clause 14 includes the subject matter of Clause 13, and further specifies that the shuttle is operable to electrical connect to the sample during ion beam milling and the electronic interface is operable to establish the voltage of a sample situated in the shuttle or determine the impedance or the voltage associated with the sample situated in the sample during the ion beam milling.

Clause 15 includes the subject matter of any of Clauses 1-15 and further specifies that at least one of the first insulator and the second insulator defines a respective aperture through which at least one of the first electrical contact and the second electrical contact extend to electrically contact at least one of the first conductive pressure plate and the second conductive pressure plate, respectively. Clause 15 also includes, in some examples, a non-conductive mask situated to shield at least a surface of one of the first conductive pressure plate or the second conductive plate across which a broad ion beam is to be directed.

Clause 16 is a method of ion beam milling a battery, including: situating a battery for exposure to an ion beam; directing an ion beam to the battery along a first axis; and with the battery situated for ion beam exposure, measuring at least one of a resistance, a conductivity, or a voltage associated with the battery.

Clause 17 includes the subject matter of Clause 16, and further specifies that the measuring of at least one of the impedance, the conductivity, or the voltage associated with the battery is performed during the directing of the ion beam to the battery.

Clause 18 includes the subject matter of any of Clauses 16-17, and further includes, based on a measured impedance, directing the ion beam to the battery along a second axis, different from the first axis.

Clause 19 includes the subject matter of any of Clauses 16-18, and further includes, based on the measured impedance, directing the ion beam to the battery along the second axis, different from the first axis, until an impedance of the battery is measured to be within a predetermined impedance range.

Clause 20 includes the subject matter of any of Clauses 16-19, and further includes, based on a measured voltage or current, applying a voltage or current to the battery to establish a battery voltage within a predetermined range.

Clause 21 includes the subject matter of any of Clauses 16-20, further wherein the voltage applied to the battery to establish the battery voltage within the predetermined range is applied during an exposure of the battery to the ion beam.

Clause 22 includes the subject matter of any of Clauses 16-21, and further specifies that the ion beam is directed to the battery along the second axis by rotating the battery.

Clause 23 includes the subject matter of any of Clauses 16-22, and further specifies that the first axis is at an angle greater that 75 degrees from the second axis.

Clause 24 includes the subject matter of any of Clauses 16-23, and further specifies that the first axis is substantially orthogonal to edges of a battery anode and a battery cathode.

Clause 25 includes the subject matter of any of Clauses 16-24, and further specifies that, based on the measured impedance, conductivity, or voltage associated with the battery, exposure of the battery to the ion beam along the first axis is terminated.

Clause 26 includes the subject matter of any of Clauses 16-25, and further specifies that after termination of the exposure to the ion beam, the battery is translated in a controlled environment for SEM imaging.

In view of the many possible embodiments to which the principles of the disclosure may be applied, it should be recognized that the illustrated embodiments are only preferred examples and should not be taken as limiting the scope of the disclosure.

We claim:

1. A shuttle for securing a sample, comprising:
a first jaw and a second jaw, the first jaw operable to be urged toward the second jaw, the first jaw and the second jaw defining a sample volume situated between an inner surface of the first jaw and an inner surface of the second jaw; and
a shuttle base that includes a first electrical contact and a second electrical contact electrically coupled to the sample volume proximate the first jaw and the second jaw, respectively.

2. The shuttle of claim 1, further comprising:
a first conductive pressure plate having a first surface that defines a least a first portion of perimeter surface of the sample volume and a second surface, opposite the first surface, facing the first jaw; and
a second conductive pressure plate having a first surface that defines a least a second portion of perimeter surface of the sample volume opposite the first portion and a second surface, opposite the first surface, facing the second jaw,
wherein the first conductive pressure plate and the second conductive pressure plate are operable to electrical connect to a sample situated in the sample volume in response to response to the first jaw being urged toward the second jaw.

3. The shuttle of claim 2, further comprising:
a first insulator situated at an inner surface of the first jaw to electrically insulate the first jaw from the first conductive pressure plate and a second insulator situated at an inner surface of the second jaw to electrically insulate the second jaw from the second conductive pressure plate.

4. The shuttle of claim 1, wherein the second jaw is fixed to the shuttle base.

5. The shuttle of claim 1, further comprising:
a first insulator situated at an inner surface of the first jaw to electrically insulate the first jaw from the sample volume; and
a second insulator situated at an inner surface of the second jaw to electrically insulate the second jaw from the sample volume.

6. The shuttle of claim 5, wherein the second jaw is fixed to the shuttle base.

7. The shuttle of claim 2, further comprising a screw mechanism secured to the shuttle base and operable to urge the first conductive pressure plate toward the second conductive pressure plate.

8. The shuttle of claim 1, wherein the shuttle base defines a shuttle axis of translation.

9. The shuttle of claim 8, wherein the shuttle base has a dovetailed cross-section in a plane perpendicular to a shuttle axis of translation.

10. The shuttle of claim 8, wherein the shuttle base defines an aperture operable to releasably retain a positioning member.

11. A shuttle system, comprising:
the shuttle of claim 9; and
a shuttle guide engageable with the shuttle base so that the shuttle is translatable along the shuttle axis of translation as engaged with the shuttle guide.

12. The shuttle system of claim 11, wherein the shuttle base and the shuttle guide have complementary engageable dovetail cross-sections that are perpendicular to the shuttle axis of translation.

13. A shuttle system, comprising:
the shuttle of claim 9; and
an electronic interface electrically coupled to the first electrical contact and the second electrical contact of the shuttle base and operable to establish a voltage of a sample situated in the shuttle or determine an impedance or a voltage associated with the sample situated in the shuttle.

14. The shuttle system of claim 13, wherein the shuttle is operable to electrical connect to the sample during ion beam milling and the electronic interface is operable to establish the voltage of a sample situated in the shuttle or determine the impedance or the voltage associated with the sample situated in the sample during the ion beam milling.

15. The shuttle of claim 3, wherein at least one of the first insulator and the second insulator defines a respective aperture through which at least one of the first electrical contact and the second electrical contact extend to electrically contact at least one of the first conductive pressure plate and the second conductive pressure plate, respectively.

16. The shuttle of claim 1, further comprising:
a non-conductive mask situated to shield at least a surface of one of the first conductive pressure plate or the second conductive plate across which a broad ion beam is to be directed.

17. A method of ion beam milling a battery, comprising:
situating a battery for exposure to an ion beam;
directing an ion beam to the battery along a first axis; and
with the battery situated for ion beam exposure, measuring at least one of an impedance, a conductivity, or a voltage associated with the battery.

18. The method of claim 17, wherein the measuring of at least one of the impedance, the conductivity, or the voltage associated with the battery is performed during the directing of the ion beam to the battery.

19. The method of claim 17, further comprising, based on a measured impedance, directing the ion beam to the battery along a second axis, different from the first axis.

20. The method of claim 19, further comprising, based on the measured impedance, directing the ion beam to the battery along the second axis, different from the first axis, until an impedance of the battery is measured to be within a predetermined impedance range.

21. The method of claim 17, further comprising, based on a measured voltage or current, applying a voltage or current to the battery to establish a battery voltage within a predetermined range.

22. The method of claim 21, further wherein the voltage or current applied to the battery to establish the battery voltage within the predetermined range is applied during an exposure of the battery to the ion beam.

23. The method of claim 20, wherein the ion beam is directed to the battery along the second axis by rotating the battery.

24. The method of claim 20, wherein the first axis is at an angle greater that 75 degrees from the second axis.

25. The method of claim 17, wherein the first axis is substantially orthogonal to edges of a battery anode and a battery cathode.

26. The method of claim 17, wherein, based on the measured impedance, conductivity, or voltage associated with the battery, exposure of the battery to the ion beam along the first axis is terminated.

27. The method of claim 26, wherein after termination of the exposure to the ion beam, the battery is translated in a controlled environment for SEM imaging.
